(19) United States
(12) Patent Application Publication
(10) Pub. No.: US 2004/0129557 A1
(43) Pub. Date: Jul. 8, 2004

(54) Method of forming non-oxide thin films using negative sputter ion beam source

(75) Inventors: Namwoong Paik, Hackensack, NJ (US); Minho Sohn, Glen Rock, NJ (US); Dae-Il Kim, Riverdale, NJ (US)

Correspondence Address: MORGAN LEWIS & BOCKIUS LLP, 1111 PENNSYLVANIA AVENUE NW, WASHINGTON, DC, 20004, US

(73) Assignee: Plasmion Corporation

(21) Appl. No.: 10/695,485

(22) Filed: Oct. 29, 2003

Related U.S. Application Data
(63) Continuation-in-part of application No. 10/300,783, filed on Nov. 21, 2002.

(51) Int. Cl. C23C 14/32

(52) U.S. Cl. 204/192.12; 204/192.15

(57) ABSTRACT

A method of forming an non-oxide thin film includes introducing a work function reducing agent onto a surface of a sputter target facing into a substrate in a process chamber, providing an inert gas into the process chamber, ionizing the inert gas, thereby generating a plurality of electrons, disintegrating a plurality of negatively charged ions from the sputter target, and forming the non-oxide thin film on the substrate from the negatively charged ions.

This Application claims priority under 35 U.S.C. § 120 as a continuation-in-part of U.S. application Ser. No. 10/300,783, filed Nov. 21, 2002, which is incorporated in its entirety herein by reference.

### BACKGROUND OF THE INVENTION

1. Field of the Invention

The present invention relates to a thin film, and more particularly, to a method of forming non-oxide thin films using a negative sputter ion beam source. Although the present invention is suitable for a wide scope of applications, it is particularly suitable for forming non-oxide thin films such as various metallic thin films and diamond-like-carbon films having desirable characteristics in high density, high adhesion force, high hardness, good step coverage, and atomically smooth surface.

2. Discussion of the Related Art

Today's industry needs high quality thin films, which only can be achieved by sophisticated control of film properties such as higher density, atomically smooth surface, high hardness, crystalline structure at lower temperature, and better step coverage in high aspect ratio trench. Ion beam induced film growth can greatly enhance the properties of the thin films by the bombardment of energetic target particles.

Several deposition methods have been attempted to achieve a good quality of thin films by using molecular beam epitaxy (MBE), R.F. magnetron sputtering, cathodic arc, plasma enhanced chemical vapor deposition (PECVD), reactive pulsed laser deposition (RPLD), and ion beam assisted deposition (IBAD).

Even with the development of those sophisticated deposition techniques, there remain several problems yet to be resolved in depositing the metallic and diamond-like carbon thin film. For example, low density of the thin films; poor adhesion force between the substrate and thin metallic films such as copper, silver, or gold; rough surface morphology of the thin films; and poor step coverage in high aspect ratio trench.

In the case of diamond-like-carbon film in hard disk applications, the film is used as an overcoat on top of the magnetic layers to protect the magnetic layers from wear and corrosion. For the next generation of products, it is critically important to have the overcoat layer as thin as 20 Å or lower and maintain the wear and corrosion resistance. In order to have such properties at low thickness, the deposited diamond-like-carbon thin film should be highly dense. One of the most efficient ways to produce dense films is known as an ion beam related deposition technique. An energetic bombardment of the target particles on the surface can densify the thin film by the excessive surface mobility of atoms. Also, the particles provide extra energies to the surface and eventually enhance the packing density of thin films.

### SUMMARY OF THE INVENTION

Accordingly, the present invention is directed to a method of forming non-oxide thin films using a negative sputter ion beam (NSIB) source that substantially obviates one or more of problems due to limitations and disadvantages of the related art.

Another object of the present invention is to provide a method of forming non-oxide thin films using a negative sputter ion beam source that has enhanced characteristics in high density, high adhesion force, high hardness, good step coverage, and atomically smooth surface.

Additional features and advantages of the invention will be set forth in the description which follows and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a method of forming a non-oxide thin film includes introducing a work function reducing agent onto a surface of a sputter target facing into a substrate in a process chamber, providing an inert gas into the process chamber, ionizing the inert gas, thereby generating a plurality of electrons, disintegrating a plurality of negatively charged ions from the sputter target, and forming the non-oxide thin film on the substrate from the negatively charged ions.

In another aspect of the present invention, a method of forming a non-oxide thin film using a magnetron sputter system includes, evacuating the process chamber to maintain a base pressure, introducing a work function reducing agent onto a surface of a sputter target facing into the substrate, providing an inert gas into the process chamber, maintaining a process pressure of the process chamber, ionizing the inert gas, thereby generating a plurality of electrons, confining the electrons in close proximity to the surface of the sputter target, disintegrating a plurality of negatively charged ions from the sputter target, and forming the non-oxide thin film on the substrate from the negatively charged ions.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention.

In the drawings:

FIG. 1 illustrates a schematic diagram of a process chamber for forming various metallic and diamond-like-carbon thin films according to the present invention;

FIG. 2 illustrates the density measurements of diamond-like-carbon thin film formed by using a negative sputter ion beam source according to the present invention and by using the conventional magnetron sputter method;

FIG. 3A is an atomic force microscope image (AFM) of the diamond-like-carbon thin film by using the conventional magnetron sputter method;

FIG. 3B is an atomic force microscope (AFM) image of the diamond-like-carbon thin film by using the negative sputter ion beam source according to the present invention. A medium ion beam energy, 600 eV, is employed for the diamond-like carbon film generation;

FIG. 3C is an atomic force microscope (AFM) image of the diamond-like-carbon thin film by using the negative sputter ion beam source according to the present invention. A high ion beam energy, 800 eV, is employed for the diamond-like carbon film generation;

FIG. 4A is the picture of copper thin film formed on a glass substrate by using a conventional magnetron sputter method. The copper thin film is easily peeled off by the peeling test;

FIG. 4B is the picture of copper thin film formed on the glass substrate by using the negative sputter ion beam source according to the present invention. The copper thin film is not peeled off by the peeling test;

FIG. 5 is the adhesion force measurement of the copper thin film formed by using the conventional magnetron sputter method and by using the negative sputter ion beam source according to the present invention;

FIG. 6A illustrates the scanning electron microscope (SEM) images of the copper thin film formed in trenches by using a conventional magnetron sputter method;

FIG. 6B illustrates scanning electron microscope (SEM) images of the copper thin film formed in a trench by using the negative sputter ion beam source according to the present invention;

FIG. 7A illustrates an atomic force microscope (AFM) image of silver thin film formed by using a conventional magnetron sputter method;

FIG. 7B illustrates an atomic force microscope (AFM) image of silver thin film formed by using the negative sputter ion beam source according to the present invention;

### DETAILED DESCRIPTION OF THE ILLUSTRATED EMBODIMENTS

Reference will now be made in detail to the illustrated embodiments of the present invention, examples of which are illustrated in the accompanying drawings. Wherever possible, the same reference numbers will be used throughout the drawings to refer to the same or like parts.

In the present invention, a negative sputter ion beam (NSIB) source is used to form various metallic thin films, such as copper (Cu), silver (Ag), gold (Au), aluminum (Al), molybdenum (Mo), tungsten (W), Titanium (Ti), and Tantalum (Ta), Chromium (Cr), and diamond-like-carbon (DLC) thin film. NSIB source utilizes negative ions formed on the cesiated target surface. The negative ion formation on the cesiated surface is disclosed in U.S. Pat. No. 5,466,941, which is hereby incorporated by reference in its entirety. Detailed characteristics of the non-oxide films (metallic and diamond-like-carbon thin films) formed by NSIB source, such as high density, high adhesion force, high hardness, good step coverage, and atomically smooth surface will be discussed in the present invention.

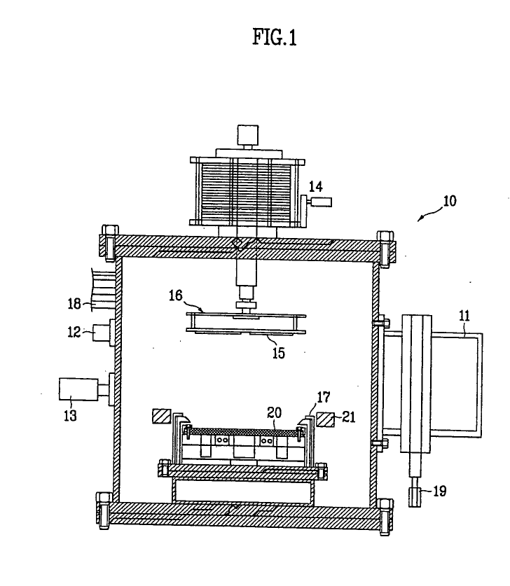

FIG. 1 illustrates a schematic diagram of a process chamber for forming various non-oxide thin films according to the present invention.

As shown in FIG. 1, a process chamber 10 may include a Cryo pump 11, a thermocouple gauge 12, an ion gauge 13, a sample transport system 14, a substrate 15, a substrate holder 16, a negative sputter ion beam source 17, a mass flow controller (MFC) 18 for argon, a gate valve 19, a sputter target 20, and a cesium injector 21.

More specifically, the Cryo pump 11 (CTI-cryogenics) is attached to the process chamber 10, so that a base chamber pressure is maintained at about 10⁻⁷ to 10⁻⁶ Torr. The base chamber pressure is monitored using the thermocouple gauge 12 and the ion gauge 13. A typical operating pressure with argon plasma is in the range of 10⁻⁴ and 10⁻² Torr.

At the bottom of the process chamber 10, an 8-inch magnetron sputter type negative ion beam source is placed to generate negative ions from the target surface. For example, an 8-inch diameter and 0.25-inch thick 99.999% copper target may be used as a target to form a copper thin film on the substrate 15.

The substrate holder 16 with linear motion equipment is capable of adjusting a target-to-substrate distance. A silicon wafer, plastic, or a glass substrate may be used as the substrate 15 depending upon different applications. During deposition, the gate valve 19, for example an 8-inch manual type, is located between the Cryo pump 11 and the process chamber 10 to control the process pressure. To reduce the work function of the sputter target 20, a work function reducing agent, such as cesium (Cs), rubidium (Rb), potassium (K), sodium (Na), and lithium (Li), is injected onto the surface of the sputter target 20 from cesium injector 21.

Thereafter, an inert gas, such as argon, is introduced into the process chamber 10. In order to ionize the inert gas, a voltage, such as straight DC, pulsed DC, and RF power supply, may be applied to the sputter target 20. For example, the applied voltage may be in the range of about 100 to 1000 V.

With the help of the work function reducing agent on the sputter target 20, a plurality of negatively charged ions are disintegrated from the sputter target 20 and move towards the substrate 15. The negatively charged ions form various thin films on the substrate 15. Depending upon a target material, various thin films, such as copper (Cu), silver (Ag), gold (Au), aluminum (Al), molybdenum (Mo), tungsten (W), Titanium (Ti), and Tantalum (Ta) and diamond-like-carbon thin film, may be obtained by using the above-described method (i.e., NSIB source).

The deposited various thin films are measured in various characteristics, such as density, adhesion force, step coverage, and surface roughness. The density of diamond-like-carbon thin film is measured by X-ray reflectivity. The density data suggests that the density of diamond-like-carbon thin film in the present invention is much higher than that of diamond-like-carbon thin films made by normal sputtering.

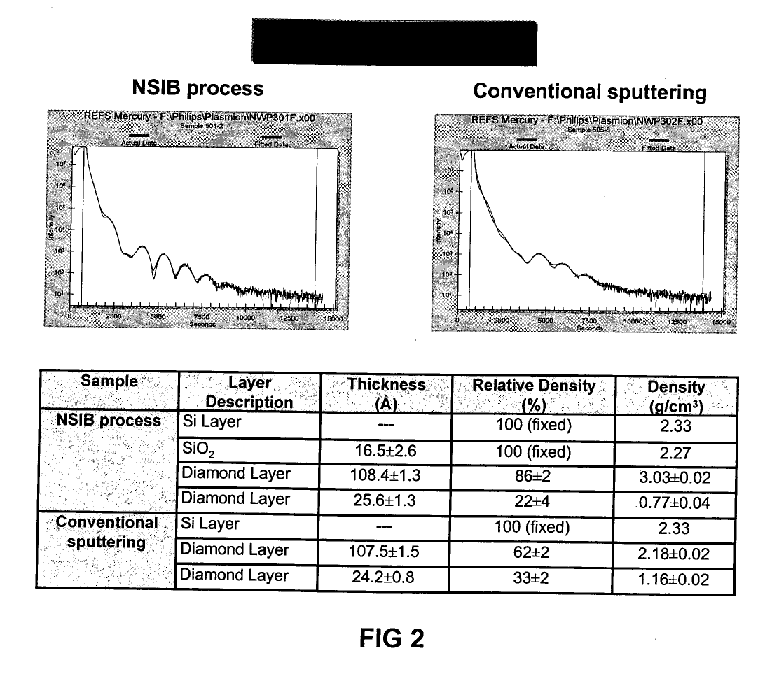

FIG. 2 illustrates the density measurements of diamond-like-carbon thin film formed by using a negative sputter ion beam source according to the present invention and by using a conventional magnetron sputter method.

As shown in FIG. 2, the measurement shows that the diamond-like-carbon thin film formed by using a negative sputter ion beam source has the film density as high as 3.03 g/cm³. This is a very high film density value compared to the film density, 2.18 g/cm³, obtained by the conventional magnetron sputter method.

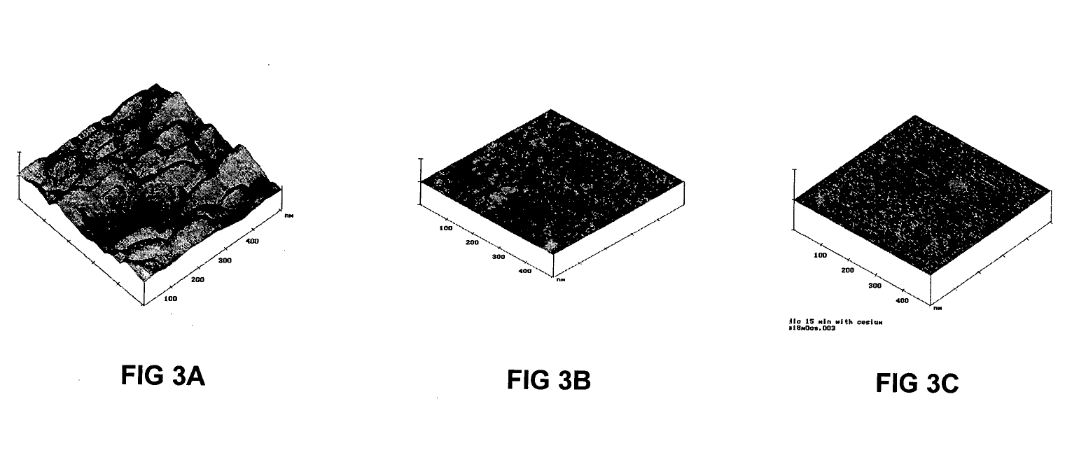

An atomic force microscope (AFM) is employed to obtain the surface morphology data. A 500 nm×500 nm area is scanned at a tapping mode. FIG. 3A is an AFM image of the diamond-like-carbon thin film on the silicon substrate by using the conventional magnetron sputter method. FIGS. 3B to 3C are AFM images of the diamond-like-carbon thin films on the silicon substrate by using the negative sputter ion beam source with different ion beam energies. At a high ion beam energy condition, the surface becomes smoother because a high-energy ion bombardment provides the adatoms with high surface mobility.

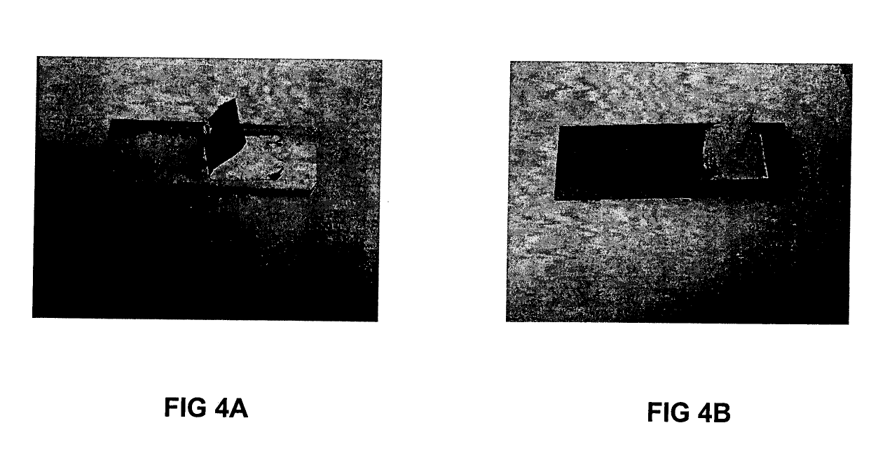

FIG. 4A is a picture of copper thin film formed on the glass substrate by using the conventional magnetron sputter method, while FIG. 4B is a picture of copper thin film formed on the glass substrate by using the negative sputter ion beam source according to the present invention. As shown in FIGS. 4A and 4B, the copper thin film made by the conventional magnetron sputter method peels off very easily by the peeling test; however, the copper thin film made by the negative sputter ion beam source does not peel off from the glass substrate. This is due to the high-energy ion bombardment provided by NSIB source in the present invention. The high-energy ion bombardment can generate the mixing layer at the interface between the copper film and the glass substrate and the mixing layer provides the excellent adhesion of the copper thin film.

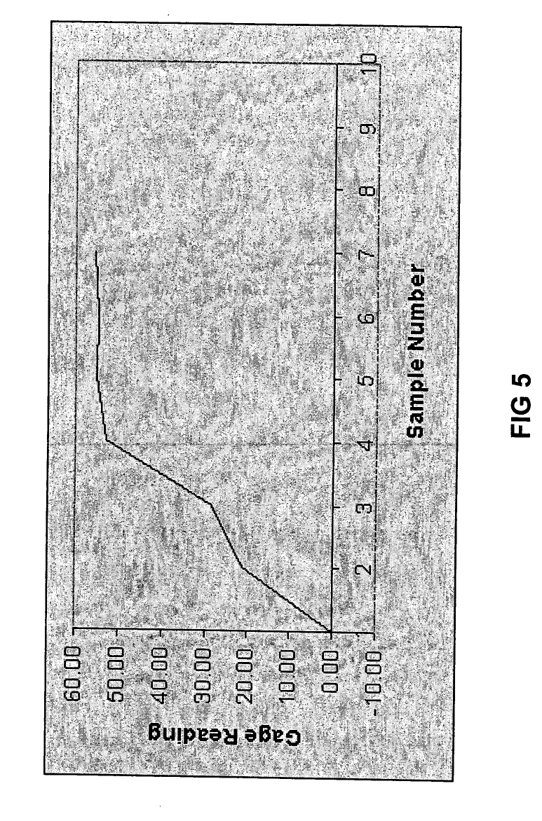

FIG. 5 is the adhesion force measurement of the copper thin film formed by using the conventional magnetron sputter method and the negative sputter ion beam source according to the present invention. The adhesion force is measured by the pulling test. The adhesion force of the copper thin film formed by using the negative sputter ion beam source is higher than 50 kg/cm². This is more than two fold higher than 20 kg/cm², which is the adhesion force of copper thin film made by the conventional magnetron sputter method.

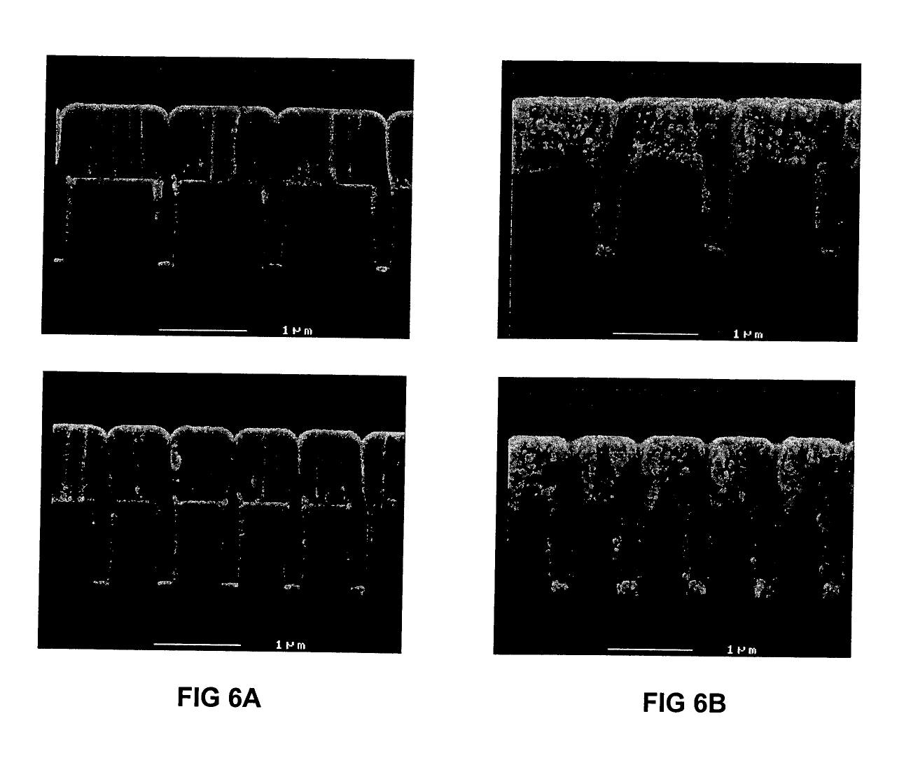

FIG. 6A illustrates the scanning electron microscope (SEM) image of the copper thin film formed in trenches by using the conventional magnetron sputter method. The transition to copper metallization for sub-100 nm device requires the deposition of thin conformal copper seed layers on increasingly higher aspect ratio dual damascene structure. It is critical to have the copper seed layer continuous and adequate in sidewall and bottom coverage to carry the current for the electroplating process. The conventional magnetron sputter method typically generates big overhang, as shown in FIG. 6A, and makes poor sidewall coverage. However, as illustrated in FIG. 6B, the negative sputter ion beam source according to the present invention generates the conformal deposition of copper films in trenches 0.2 μm wide and 1.0 μm deep. By using the negative sputter ion beam source, the copper negative ions generated from the target carry the high kinetic energy and directionality. In addition, the kinetic energy of the copper ions can be controlled by applying bias to the substrate. Therefore, the depositing trajectories of the sputtered copper particles can be more controllable and potentially more conformal in high aspect ratio trenches.

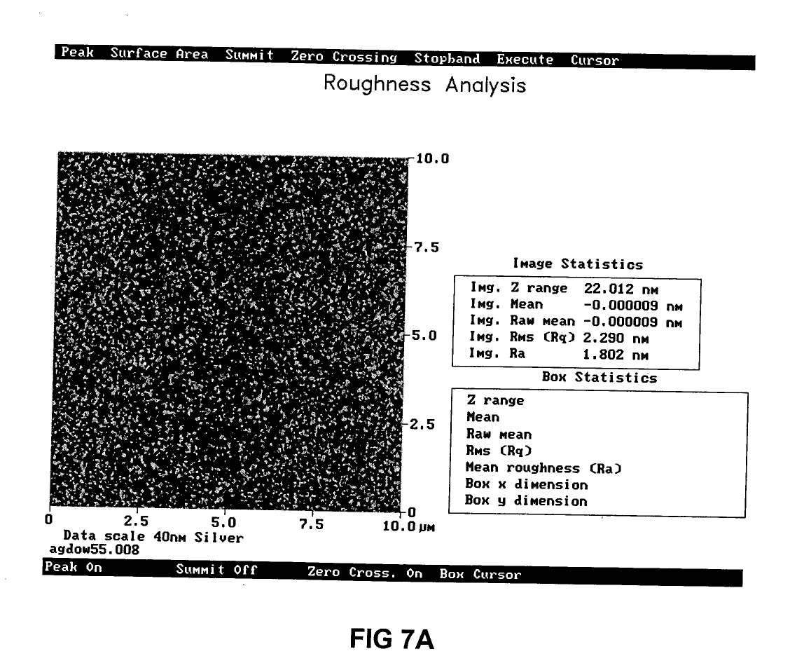

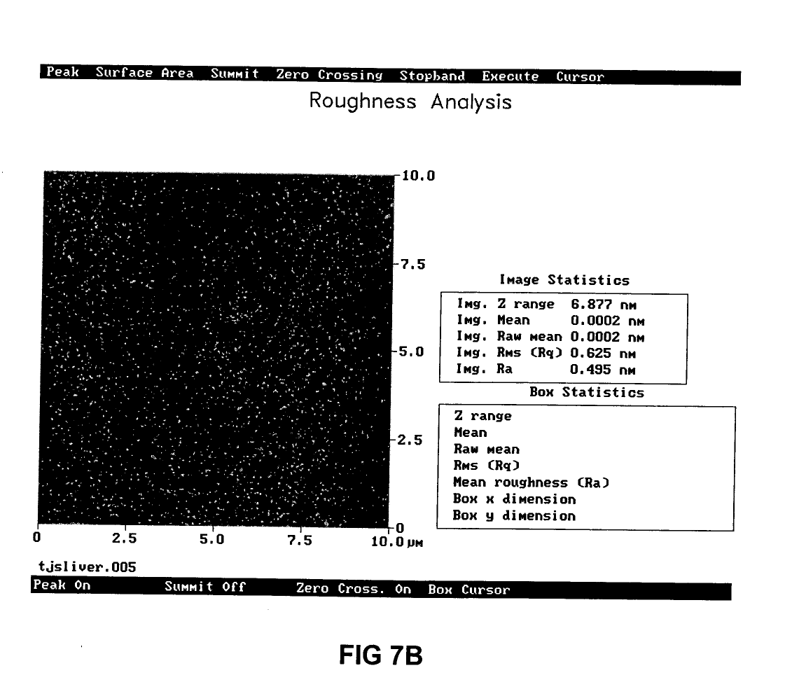

FIGS. 7A and 7B respectively illustrate the atomic force microscope (AFM) image of silver thin films formed by the conventional method and by the negative sputter ion beam source according to the present invention. As shown in FIGS. 7A and 7B, the silver thin film formed by the conventional sputtering method has a very rough surface morphology due to the agglomeration of the atoms during the thin film growth. Meanwhile, the silver thin film formed by the process in the present invention shows an extremely smooth surface morphology.

In the present invention, characteristics of the non-oxide thin films are also investigated with different deposition conditions. The overall result demonstrates that desirable metallic and diamond-like-carbon thin films are deposited by controlling the Cs flow rate even in the higher deposition rate conditions. Also, the characteristic of the metallic and diamond-like-carbon thin film is varied by changing the negative ion energy.

It will be apparent to those skilled in the art that various modifications and variations can be made in the method of forming non-oxide thin films using a negative sputter ion beam source of the present invention without departing from the spirit or scope of the inventions. Thus, it is intended that the present invention covers the modifications and variations of this invention provided they come within the scope of the appended claims and their equivalents.

What is claimed is:

1. A method of forming a non-oxide thin film, comprising:
introducing a work function reducing agent onto a surface of a sputter target facing into a substrate in a process chamber;
providing an inert gas into the process chamber;
ionizing the inert gas, thereby generating a plurality of electrons;
disintegrating a plurality of negatively charged ions from the sputter target; and
forming the non-oxide thin film on the substrate from the negatively charged ions reacted with the ionized oxygen gas.

2. The method according to claim 1, wherein the non-oxide thin film includes one of copper (Cu), silver (Ag), gold (Au), aluminum (Al), molybdenum (Mo), tungsten (W), Titanium (Ti), and Tantalum (Ta), Chromium (Cr), and diamond-like-carbon (DLC) thin film.

3. The method according to claim 1, wherein the work function reducing agent includes one of cesium, rubidium, potassium, sodium, and lithium.

4. The method according to claim 1, wherein the sputter target is applied with a voltage of one of straight DC, pulsed DC, and RF power supply.

5. The method according to claim 6, wherein the applied voltage to the sputter target is in the range of about 100 to 1000 volt.

6. The method according to claim 1, wherein the substrate is either grounded or biased with respect to the sputter target.

7. The method according to claim 1, wherein the substrate is maintained at a temperature in the range of about 25 to 500° C.

8. The method according to claim 1, wherein the process chamber has a process pressure in the range of about 10⁻⁴ to 10⁻² Torr.

9. The method according to claim 1, further comprising confining the electrons in close proximity to the surface of the sputter target prior to disintegrating a plurality of negatively charged ions.

10. A method of forming an non-oxide thin film using a magnetron sputter system, comprising:
evacuating the process chamber to maintain a base pressure;
introducing a work function reducing agent onto a surface of a sputter target facing into the substrate;
providing an inert gas into the process chamber;
maintaining a process pressure of the process chamber;
ionizing the oxygen gas and the inert gas, thereby generating a plurality of electrons;
confining the electrons in close proximity to the surface of the sputter target;
disintegrating a plurality of negatively charged ions from the sputter target; and
forming the non-oxide thin film on the substrate from the negatively charged ions reacted with the ionized oxygen gas.

11. The method according to claim 12, wherein the non-oxide thin film includes one of copper (Cu), silver (Ag), gold (Au), aluminum (Al), molybdenum (Mo), tungsten (W), Titanium (Ti), and Tantalum (Ta), Chromium (Cr), and diamond-like-carbon (DLC) thin film.

12. The method according to claim 12, wherein the work function reducing agent includes one of cesium, rubidium, potassium, sodium, and lithium.

13. The method according to claim 12, wherein the sputter target is applied with a voltage of one of straight DC, pulsed DC, and RF power supply.

14. The method according to claim 17, wherein the applied voltage to the sputter target is in the range of about 100 to 1000 volt.

15. The method according to claim 12, wherein the substrate is either grounded or biased with respect to the sputter target.

16. The method according to claim 12, wherein the rate is maintained at a temperature in the range of about 25 to 500° C.

17. The method according to claim 12, wherein the process pressure is in the range of about 10⁻⁴ to 10⁻² Torr.
